(19) United States
(12) Patent Application Publication
(10) Pub. No.: US 2008/0179671 A1
(43) Pub. Date: Jul. 31, 2008

(54) SEMICONDUCTOR APPARATUS

(75) Inventors: Wataru SAITO, Kanagawa-ken (JP); Syotaro ONO, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/020,288

(22) Filed: Jan. 25, 2008

(30) Foreign Application Priority Data
Jan. 31, 2007 (JP) 2007-021337

(51) Int. Cl. H01L 29/78

(52) U.S. Cl. 257/341; 257/E29.256

(57) ABSTRACT

A semiconductor apparatus includes: a first first-conductivity-type semiconductor layer; a second first-conductivity-type semiconductor layer provided on a major surface of the first first-conductivity-type semiconductor layer in a device region and a termination region outside the device region; a third second-conductivity-type semiconductor layer being adjacent to the second first-conductivity-type semiconductor layer, forming a periodic array structure; a field insulating film provided on the second first-conductivity-type semiconductor layer and the third second-conductivity-type semiconductor layer in the termination region; a first field plate electrode provided on the field insulating film and connected to the second main electrode or the control electrode; and a second field plate electrode. The second field plate electrode partly overlies the first field plate electrode through intermediary of an insulating film and extends on the field insulating film outside the first field plate electrode. The second field plate electrode is floating in potential.

### CROSS-REFERENCE TO RELATED APPLICATIONS

This application is based upon and claims the benefit of priority from the prior Japanese Patent Application No. 2007-021337, filed on Jan. 31, 2007; the entire contents of which are incorporated herein by reference.

### BACKGROUND OF THE INVENTION

1. Field of the Invention

This invention relates to a semiconductor apparatus, and more particularly to a vertical semiconductor apparatus suitable for power electronics applications.

2. Background Art

The ON resistance of a vertical power MOSFET (metal-oxide-semiconductor field effect transistor) greatly depends on the electric resistance of its conduction layer (drift layer). The dopant concentration that determines the electric resistance of the drift layer cannot exceed a maximum limit, which depends on the breakdown voltage of a pn junction between the base and the drift layer. Thus there is a tradeoff between the device breakdown voltage and the ON resistance. Improving this tradeoff is important for low power consumption devices. This tradeoff has a limit determined by the device material. Overcoming this limit is the way to realizing devices with low ON resistance beyond existing power devices.

As an example MOSFET to solve this problem, a structure with p-type pillar layers and n-type pillar layers buried in the drift layer is known as a super-junction structure. In the super-junction structure, a non-doped layer is artificially produced by equalizing the amount of charge (amount of impurities) contained in the p-type pillar layer with that contained in the n-type pillar layer. Thus, while holding a high breakdown voltage, a current is passed through the highly doped n-type pillar layer. Hence a low ON resistance beyond the material limit is realized. In order to hold a high breakdown voltage, the amount of impurities in the n-type pillar layer and the p-type pillar layer needs to be accurately controlled.

Such a MOSFET having a super-junction structure in the drift layer is different also in the design of its termination structure from normal power MOSFETs. Like the device section, the termination section also needs to hold a high breakdown voltage. Hence a super-junction structure may be formed also in the termination section (e.g., JP-A 2001-135819 (Kokai)). In this case, because the impurity concentration in the n-type pillar layer and the p-type pillar layer is higher than the concentration in the drift layer of normal power MOSFETs, such a highly doped pillar layer located in the termination section hampers the depletion layer from extending outward upon application of high voltage, and electric field concentration is likely to occur at the edge of the p-type base layer connected to the source electrode. Thus the breakdown voltage of the termination region is likely to decrease.

In order to prevent the decrease of the termination breakdown voltage, it is necessary to force the depletion layer to extend to the outer periphery of the device. One of the structures for realizing this is the field plate structure. At a low voltage, a depletion layer extends from the surface of the drift layer of the termination region through the insulating film below the field plate electrode connected to the source electrode or the gate electrode. The surface depletion layer is joined with the depletion layer located at the junction between the p-type pillar layer and the n-type pillar layer, and the drift layer below the field plate electrode is entirely depleted. Thus the depletion layer spreads laterally in the termination region, preventing electric field concentration at the edge of the p-type pillar layer, and a high termination breakdown voltage can be obtained.

Because the field plate electrode is connected to the source electrode or the gate electrode, the drain voltage is applied to the field plate electrode and the underlying insulating film. On the other hand, the depletion layer does not easily extend into the drift layer outside the field plate electrode. Hence the electric field directly below the edge of the field plate electrode unfortunately increases. That is, electric field concentration is likely to occur at the edge of the field plate electrode. In order to prevent electric field concentration at the edge of the field plate electrode, the insulating film needs to be thickened. However, if the insulating film is formed thick, the substrate is likely to warp due to the difference in thermal expansion coefficient as compared with the semiconductor layer (silicon). Thus it is currently difficult to realize a termination structure that is supposed to exhibit a high breakdown voltage in principle.

### SUMMARY OF THE INVENTION

According to an aspect of the invention, there is provided a semiconductor apparatus including: a first first-conductivity-type semiconductor layer; a second first-conductivity-type semiconductor layer provided on a major surface of the first first-conductivity-type semiconductor layer in a device region and a termination region outside the device region, the device region allowing a main current path to be formed therein in a vertical direction generally perpendicular to the major surface of the first first-conductivity-type semiconductor layer; a third second-conductivity-type semiconductor layer being adjacent to the second first-conductivity-type semiconductor layer, provided on the major surface of the first first-conductivity-type semiconductor layer, and forming a periodic array structure in combination with the second first-conductivity-type semiconductor layer in a lateral direction generally parallel to the major surface of the first first-conductivity-type semiconductor layer; a first main electrode electrically connected to the first first-conductivity-type semiconductor layer; a fourth second-conductivity-type semiconductor region provided on the third second-conductivity-type semiconductor layer in the device region; a fifth first-conductivity-type semiconductor region selectively provided in a surface of the fourth second-conductivity-type semiconductor region; a second main electrode provided in contact with the fifth first-conductivity-type semiconductor region and the fourth second-conductivity-type semiconductor region; a control electrode provided on the fifth first-conductivity-type semiconductor region, the fourth second-conductivity-type semiconductor region, and the second first-conductivity-type semiconductor layer via a gate insulating film; a field insulating film provided on the second first-conductivity-type semiconductor layer and the third second-conductivity-type semiconductor layer in the termination region; a first field plate electrode provided on the field insulating film and connected to the second main electrode or the control electrode; and a second field plate electrode partly overlying the first field plate electrode through intermediary of an insulating film and extending on the field insulating film outside the first field plate electrode, the second field plate electrode being floating in potential.

According to an aspect of the invention, there is provided a semiconductor apparatus including: a first first-conductivity-type semiconductor layer; a second first-conductivity-type semiconductor layer provided on a major surface of the first first-conductivity-type semiconductor layer in a device region and a termination region outside the device region, the device region allowing a main current path to be formed therein in a vertical direction generally perpendicular to the major surface of the first first-conductivity-type semiconductor layer; a third second-conductivity-type semiconductor layer being adjacent to the second first-conductivity-type semiconductor layer, provided on the major surface of the first first-conductivity-type semiconductor layer, and forming a periodic array structure in combination with the second first-conductivity-type semiconductor layer in a lateral direction generally parallel to the major surface of the first first-conductivity-type semiconductor layer; a first main electrode electrically connected to the first first-conductivity-type semiconductor layer; a fourth second-conductivity-type semiconductor region provided on the third second-conductivity-type semiconductor layer in the device region; a fifth first-conductivity-type semiconductor region selectively provided in a surface of the fourth second-conductivity-type semiconductor region; a second main electrode provided in contact with the fifth first-conductivity-type semiconductor region and the fourth second-conductivity-type semiconductor region; a control electrode provided on the fifth first-conductivity-type semiconductor region, the fourth second-conductivity-type semiconductor region, and the second first-conductivity-type semiconductor layer via a gate insulating film; a field insulating film provided on the second first-conductivity-type semiconductor layer and the third second-conductivity-type semiconductor layer in the termination region; a first field plate electrode provided on the field insulating film and connected to the second main electrode or the control electrode; a second field plate electrode partly overlying the first field plate electrode through intermediary of an insulating film and extending on the field insulating film outside the first field plate electrode, the second field plate electrode being floating in potential, and a fourth field plate electrode extending on the field insulating film outside the first field plate electrode, the fourth field plate electrode being floating in potential, and the fourth field plate electrode being spaced from the second filed plate electrode.

### BRIEF DESCRIPTION OF THE DRAWINGS

FIG. 1 is a cross-sectional view schematically showing the configuration of a semiconductor apparatus according to a first embodiment of the invention;

FIG. 2 is a schematic cross-sectional view showing a modification example of the semiconductor apparatus of the same;

FIG. 3 is a schematic cross-sectional view showing another modification example of the semiconductor apparatus of the same;

FIG. 4 is a schematic cross-sectional view showing still another modification example of the semiconductor apparatus of the same;

FIG. 5 is a cross-sectional view schematically showing the configuration of a semiconductor apparatus according to a second embodiment of the invention;

FIG. 6 is a schematic cross-sectional view showing a modification example of the semiconductor apparatus of the same;

FIGS. 7A and 7B are cross-sectional views schematically showing the configuration of a semiconductor apparatus according to a third embodiment of the invention; and

FIGS. 8A and 8B are cross-sectional views schematically showing the configuration of a semiconductor apparatus according to a fourth embodiment of the invention.

### DETAILED DESCRIPTION OF THE INVENTION

The semiconductor apparatus according to embodiments of the invention will now be described with reference to the drawings, taking a power MOSFET as an example. In the following embodiments, it is assumed that the first conductivity type and the second conductivity type are n-type and p-type, respectively. Like elements in the drawings are marked with like reference numerals.

### First Embodiment

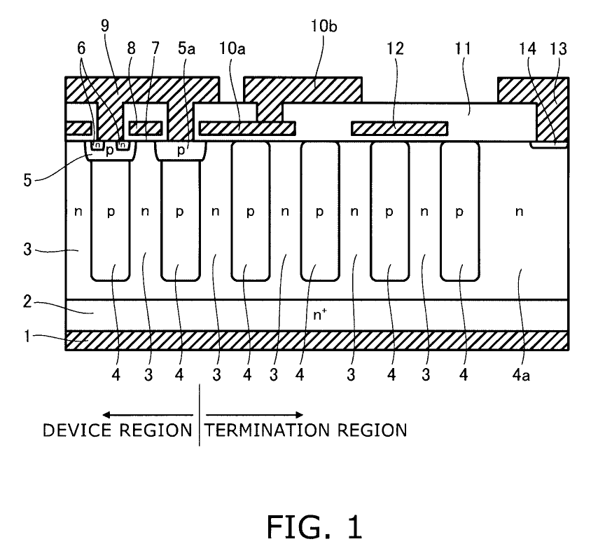

FIG. 1 is a cross-sectional view schematically showing the configuration of a semiconductor apparatus according to a first embodiment of the invention.

The semiconductor apparatus according to this embodiment is a vertical device in which a main current path is formed in the vertical direction (the direction generally perpendicular to the major surface of the semiconductor layer) connecting between a first main electrode and a second main electrode provided on the frontside and the backside of the semiconductor layer, respectively. The semiconductor apparatus according to this embodiment comprises a device region in which the main current path is formed and a termination region surrounding outside the device region.

On the major surface of a drain layer 2 serving as a first first-conductivity-type semiconductor layer of n⁺-type silicon having a high impurity concentration, n-type pillar layers 3 of n-type silicon serving as second first-conductivity-type semiconductor layers and p-type pillar layers 4 of p-type silicon serving as third second-conductivity-type semiconductor layers are provided.

The n-type pillar layers 3 and the p-type pillar layers 4 are periodically arrayed, alternately adjacent (in pn junction) to each other in the lateral direction generally parallel to the major surface of the drain layer 2, constituting a so-called “super-junction structure”. The super-junction structure of the n-type pillar layers 3 and the p-type pillar layers 4 is formed not only in the device region but also in the termination region. The bottom of the n-type pillar layer 3 is in contact with the drain layer 2 and constitutes part of the main current path during ON time.

The planar pattern of the n-type pillar layers 3 and the p-type pillar layers 4 is illustratively a striped configuration. However, it is not limited thereto, but may be formed in a lattice or staggered configuration.

A base region 5 of p-type silicon is provided as a fourth second-conductivity-type semiconductor region on the p-type pillar layer 4 in the device region. Like the p-type pillar layer 4, the base region 5 is adjacent to and in pn junction with the n-type pillar layer 3. A source region 6 of n⁺-type silicon is selectively provided as a fifth first-conductivity-type semiconductor layer in the surface of the base region 5.

A gate insulating film 7 is provided on the portion extending from the n-type pillar layer 3 through the base region 5 to the source region 6. The gate insulating film 7 is illustratively a silicon oxide film having a thickness of approximately 0.1 μm. A control electrode (gate electrode) 8 is provided on the gate insulating film 7.

A source electrode 9 is provided as a second main electrode on part of the source regions 6 and the portion of the base region 5 between the source regions 6. The source electrode 9 is in contact with and electrically connected to the source region 6 and the base region 5. At the surface opposite to the major surface of the drain layer 2, a drain electrode 1 is provided as a first main electrode and electrically connected to the drain layer 2.

Like the device region, the termination region also includes a super-junction structure of n-type pillar layers 3 and p-type pillar layers 4 on the drain layer 2, and a field insulating film 11 is formed on the surface of the super-junction structure.

Field plate electrodes 10a, 10b are formed on the field insulating film 11. In forming the field plate electrode (first field plate electrode) 10a, a field insulating film 11 is formed on the super-junction structure of the termination region, and then a field plate electrode 10a is formed on the field insulating film 11 and subsequently covered with an insulating film. Consequently, the field plate electrode 10a is provided within the insulating film. In this embodiment, the insulating film below the field plate electrode 10a and the insulating film covering the field plate electrode 10a are collectively referred to as the field insulating film 11.

In part of the field insulating film 11 on the field plate electrode 10a is formed a via passing through that field insulating film 11 and reaching the field plate electrode 10a, and a field plate electrode 10b is formed on the field insulating film 11 so as to fill in the via. The field plate electrode 10a is electrically connected to the field plate electrode 10b through the via. The field plate electrode 10a is extracted through the field plate electrode 10b onto the field insulating film 11, and the field plate electrode 10b is connected to the source electrode 9. Hence the field plate electrode 10a is also connected to the source electrode 9. It is noted that the field plate electrodes 10a, 10b may be connected to the control electrode 8.

On the surface of the super-junction structure outside the field plate electrode 10a is provided a floating field plate electrode (second field plate electrode) 12 through the intermediary of the field insulating film 11. The floating field plate electrode 12 is electrically connected to nowhere, floating in potential. In forming the floating field plate electrode 12, like the field plate electrode 10a, a field insulating film 11 is formed on the super-junction structure of the termination region, and then a floating field plate electrode 12 is formed on the field insulating film 11 and subsequently covered with an insulating film. Consequently, the floating field plate electrode 12 is provided within the insulating film (field insulating film 11).

On the inner edge of the floating field plate electrode 12, through the intermediary of the field insulating film 11, the outer edge of the field plate electrode 10b overlies along the thickness. That is, part of the floating field plate electrode 12 is covered with part of the field plate electrode 10b through the intermediary of the insulating film.

A p-type field stop region 14 is formed in the surface portion of the semiconductor layer (n-type semiconductor layer) 4a in the outermost portion of the termination region so that the depletion layer does not reach the dicing line upon application of high voltage. On the surface of the field stop region 14 is provided a field stop electrode 13 in contact therewith.

In the semiconductor apparatus according to this embodiment described above, when a high voltage is applied to the drain electrode 1, a depletion layer extends from the surface of the semiconductor layer of the termination region through the field insulating film 11 below the field plate electrodes 10a, 10b connected to the source electrode 9 or the control electrode 8, and is joined with the depletion layer located at the junction between the n-type pillar layer 3 and the p-type pillar layer 4. Thus the semiconductor layer below the field plate electrodes 10a, 10b is entirely depleted.

When the depletion layer extends further laterally and reaches the floating filed plate electrode 12, the depletion layer also extends in the portion underlying the floating field plate electrode 12. That is, the floating field plate electrode 12 provided outside the field plate electrodes 10a, 10b helps the depletion layer extend also to the outside of the field plate electrodes 10a, 10b. Consequently, the depletion layer is laterally enlarged in the termination region, alleviating electric field at the edge of the outermost base region 5a, where the electric field is particularly likely to concentrate, and electric field on the surface of the semiconductor layer of the termination region. Thus a high termination breakdown voltage can be obtained. Furthermore, because the surface electric field decreases in the termination region, occurrence of hot carriers is suppressed, and a high reliability can be obtained.

The floating field plate electrode 12 is not connected to any of the source electrode 9, the control electrode 8, and the drain electrode 1, but is an electrode floating in potential. Hence the floating field plate electrode 12 has an intermediate potential between the drain potential and the source potential. Thus the voltage applied to the field insulating film 11 below the floating field plate electrode 12 can be kept low, eliminating the need to thicken the field insulating film 11 for increasing the breakdown voltage. That is, even with the thickness of the field insulating film comparable to conventional thickness, electric field concentration at the edge of the field plate electrode 10a can be prevented. Because the field insulating film 11 is not thickened, warpage of the substrate can be prevented.

Furthermore, in this embodiment, the outer edge of the field plate electrode 10b is formed so as to cover the inner edge of the floating field plate electrode 12 through the intermediary of the field insulating film 11. Hence the potential of the floating field plate electrode 12 can exhibit a gradual potential distribution from the inside (source potential side) to the outside (drain potential side) without being biased to the drain potential side, and electric field concentration can be prevented below the floating field plate electrode 12. That is, capacitive coupling between the field plate electrode 10b and the floating field plate electrode 12 opposed to each other across the field insulating film 11 helps the potential of the field plate electrode 10b affect the floating field plate electrode 12, preventing the floating field plate electrode 12 from being too strongly affected by the drain potential. This can facilitate placing the floating field plate electrode 12 at a desired intermediate potential.

According to this embodiment, even if the super-junction structure is formed in the termination region as well as in the device region as is conventional, or even if the field insulating film is not thickened, that is, using the same process as the conventional one (without additional processing load), a floating field plate electrode 12 is provided outside the field plate electrodes 10a, 10b to help the depletion layer in the termination region extend laterally. Thus a semiconductor apparatus having low ON resistance is provided while ensuring high breakdown voltage and high reliability.

The field plate electrode 10a and the floating field plate electrode 12 can be simultaneously formed from the same material (polycrystalline silicon, for example) on the field insulating film 11 after the field insulating film 11 is formed on the surface of the super-junction structure layer of the termination region. In this case, the field insulating film 11 underlying both the electrodes 10a, 12 has an equal thickness.

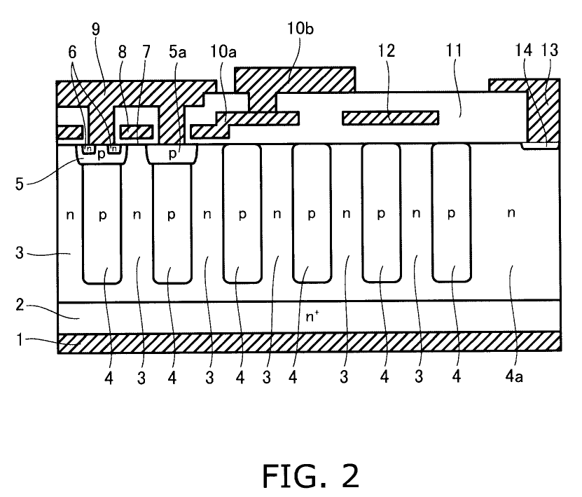

As shown in FIG. 2, if the insulating film thickness below the field plate electrode 10a is varied stepwise, for example, then the thickness of the field insulating film 11 underlying the floating field plate electrode 12 depends on which process serves to form the floating field plate electrode 12. In the case of FIG. 2, if the floating field plate electrode 12 is formed simultaneously with the control electrode 8, the insulating film thickness below the floating field plate electrode 12 equals the insulating film thickness below the control electrode 8. If the floating field plate electrode 12 is formed simultaneously with the field plate electrode 10a, the insulating film thickness below the floating field plate electrode 12 equals the insulating film thickness below the field plate electrode 10a.

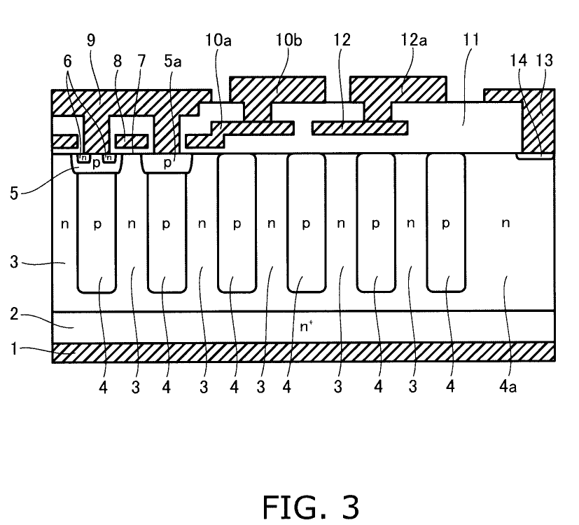

As shown in FIG. 3, a via may be formed through the thickness of the field insulating film 11 on the floating field plate electrode (second field plate electrode) 12, and a floating field plate electrode (third field plate electrode) 12a may be provided on the field insulating film 11 so as to fill in the via. The floating field plate electrode 12a is connected only to the floating field plate electrode 12 through the via, and hence floating in potential.

The floating field plate electrode 12a is formed on the field insulating film 11 overlying the floating field plate electrode 12 so as to extend to the outside of the outer edge of the floating field plate electrode 12. That is, the floating field plate electrode 12 and the floating field plate electrode 12a are formed stepwise. Hence the field insulating film 11 below the floating field plate electrodes 12, 12a has a larger thickness on the outside than on the inside (device region side). Because the floating field plate electrode 12a extends to the outside with the insulating film thickness therebelow being thicker than that below the inner floating field plate electrode 12, the depletion layer can be extended further laterally while preventing electric field concentration at the outer edge (corner portion) of the floating field plate electrode 12.

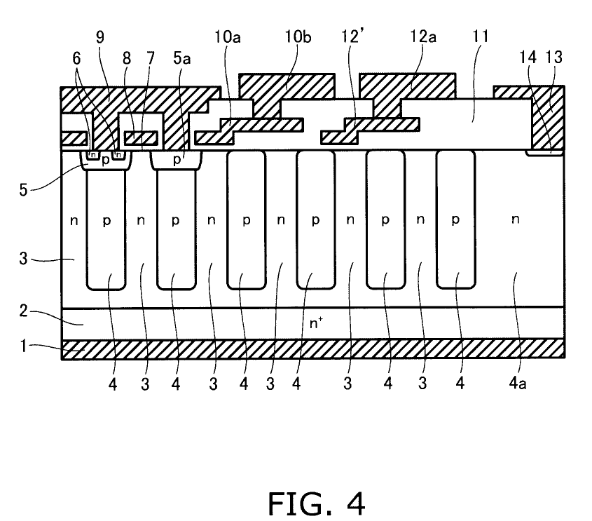

Furthermore, the floating field plate electrode 12 in FIG. 3 may be formed as a stepwise floating field plate electrode 12′ shown in FIG. 4. The thickness of the field insulating film 11 below the floating field plate electrode 12′ is thicker on the outside than on the inside (device region side). Also in this structure, the depletion layer can be extended further laterally while preventing electric field concentration at the corner portion of the floating field plate electrode 12′.

In the following, other embodiments of this invention are described. The same elements as those in the embodiments described earlier are not described in detail, but only different elements are described.

### Second Embodiment

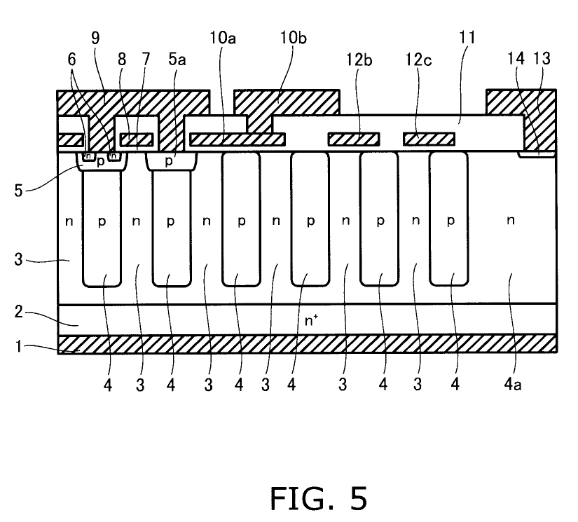

FIG. 5 is a cross-sectional view schematically showing the configuration of a semiconductor apparatus according to a second embodiment of the invention.

In this embodiment, on the field insulating film 11 outside the field plate electrodes 10a, 10b, a plurality of (two, in the example shown) floating field plate electrodes 12b, 12c spaced from each other are provided. The inner edge of the floating field plate electrode (second filed plate electrode) 12b overlies the outer edge of the field plate electrode 10b through the intermediary of the field insulating film 11, and the floating field plate electrode (fourth field plate electrode) 12c is formed outside the floating field plate electrode 12b through the intermediary of the field insulating film 11. The floating field plate electrodes 12b, 12c are each floating in potential.

Also in this embodiment, the floating field plate electrodes 12b, 12c, floating in potential, are provided outside the field plate electrodes 10a, 10b. This helps the depletion layer extend to the outside of the field plate electrodes 10a, 10b while preventing voltage increase below the floating field plate electrodes 12b, 12c. Consequently, the depletion layer is laterally enlarged in the termination region, alleviating electric field at the edge of the outermost base region 5a, and electric field on the surface of the semiconductor layer of the termination region. Thus a high termination breakdown voltage can be obtained. Furthermore, because the surface electric field decreases in the termination region, occurrence of hot carriers is suppressed, and a high reliability can be obtained.

Furthermore, also in this embodiment, the outer edge of the field plate electrode 10b is formed so as to cover the inner edge of the inner floating field plate electrode 12b through the intermediary of the field insulating film 11. Hence the potential of the field plate electrode 10b easily affects the floating field plate electrode 12b, preventing the floating field plate electrode 12b from being too strongly affected by the drain potential. This can facilitate placing the floating field plate electrode 12b and the floating field plate electrode 12c, which is affected by the potential of the floating field plate electrode 12b, at a desired intermediate potential.

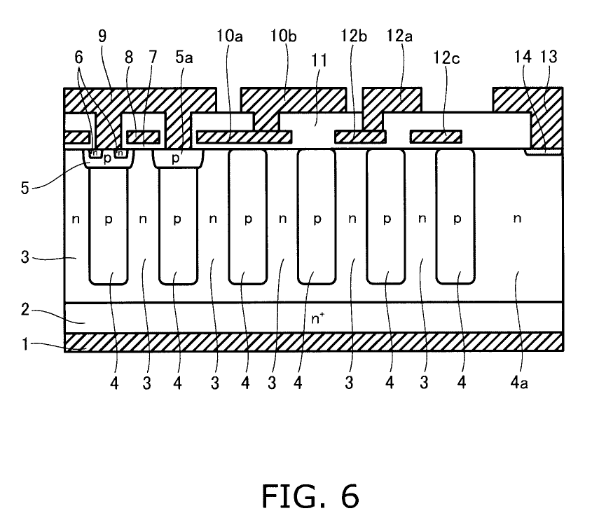

As shown in FIG. 6, in the case where a plurality of floating field plate electrodes are provided, the outer edge of the floating field plate electrode 12a connected to the inner (field plate electrode 10b side) floating field plate electrode 12b may be provided to overlie the inner edge of the outer floating field plate electrode 12c through the intermediary of the field insulating film 11.

Also in this case, the potential of the more inner (nearer to the source potential side) floating field plate electrode 12b easily affects the more outer (nearer to the drain potential side) floating field plate electrode 12c through the floating field plate electrode 12a, preventing the floating field plate electrode 12c from being too strongly affected by the drain potential. This can facilitate placing the floating field plate electrode 12c at a desired intermediate potential.

Because the floating field plate electrode 12a extends to the outside with the insulating film thickness therebelow being thicker than that below the inner floating field plate electrode 12b, the depletion layer can be extended laterally while preventing electric field concentration at the edge of the floating field plate electrode 12b.

### Third Embodiment

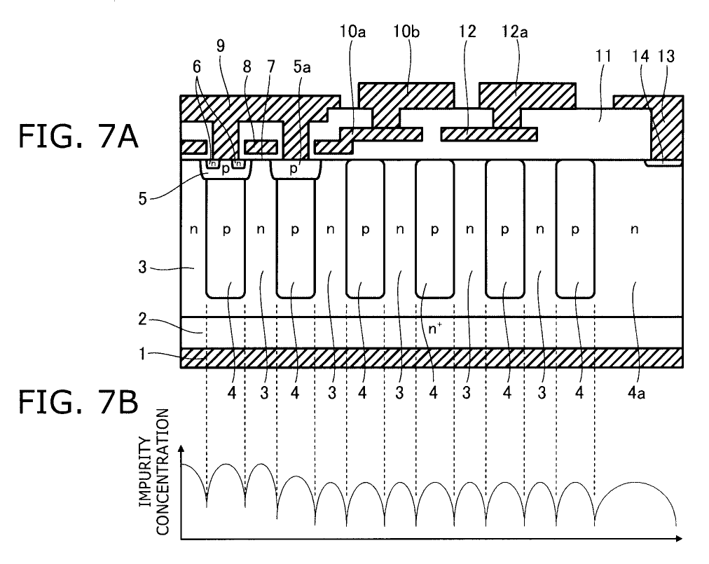

FIG. 7 is a cross-sectional view schematically showing the configuration of a semiconductor apparatus according to a third embodiment of the invention. More specifically, FIG. 7A is a cross-sectional view corresponding to the structure shown in FIG. 3. In FIG. 7B, the horizontal axis corresponds to the lateral position in the cross-sectional structure of FIG. 7A, and the vertical axis represents impurity concentration in the semiconductor layer on the drain layer 2.

In this embodiment, the impurity concentration in the super-junction structure (n-type pillar layers 3 and p-type pillar layers 4) of the termination region is lower than the impurity concentration in the super-junction (n-type pillar layers 3 and p-type pillar layers 4) of the device region. By decreasing the impurity concentration in the super-junction structure of the termination region below that of the device region, n-type pillar layers 3 and p-type pillar layers 4 in the termination region are depleted at a lower voltage than in the device region. Thus a higher termination breakdown voltage than in the device region can be obtained.

The impurity concentration in the pillar layer located at the boundary between the device region and the termination region is preferably an intermediate concentration between that in the device region and that in the termination region so as to avoid local concentration imbalance between the n-type pillar layer 3 and the p-type pillar layer 4.

### Fourth Embodiment

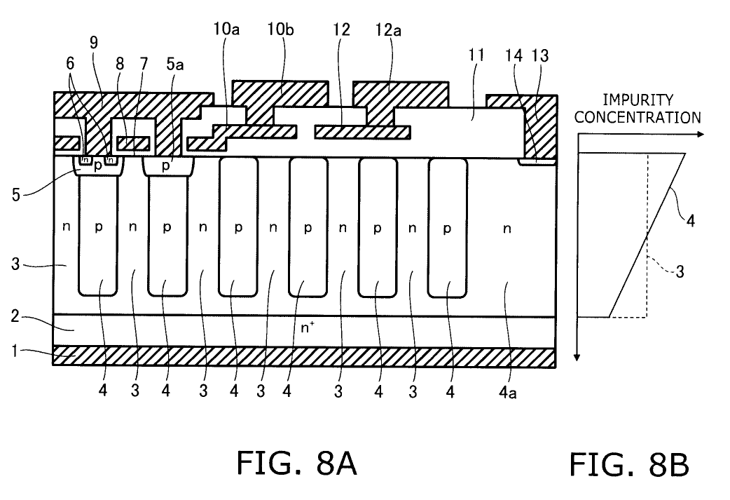

FIG. 8 is a cross-sectional view schematically showing the configuration of a semiconductor apparatus according to a fourth embodiment of the invention. More specifically, FIG. 8A is a cross-sectional view corresponding to the structure shown in FIG. 3. In FIG. 8B, the vertical axis corresponds to the vertical position in the cross-sectional structure of FIG. 8A, and the horizontal axis represents impurity concentration along the depth in the semiconductor layer on the drain layer 2.

In this embodiment, for example, the impurity concentration in the n-type pillar layer 3 is constant along the depth, whereas the impurity concentration in the p-type pillar layer 4 is gradually decreased from the source electrode 9 side toward the drain electrode 1 side. Hence the impurity concentration is higher in the p-type pillar layer 4 than in the n-type pillar layer 3 on the source electrode 9 side, whereas the impurity concentration is lower in the p-type pillar layer 4 than in the n-type pillar layer 3 on the drain electrode 1 side. If the vertical (depthwise) concentration profile is thus sloped, the breakdown voltage shows less decrease when the amount of impurities in the n-type pillar layer 3 equals that in the p-type pillar layer 4 than in the case of no slope. Thus the decrease of breakdown voltage due to process variations is prevented, and a stable breakdown voltage is obtained.

Furthermore, because the electric field at the upper and lower end of the super-junction structure decreases, a high avalanche withstand capability is obtained. When an avalanche breakdown occurs, a large amount of carriers are generated in the drift layer, and the electric field at the upper and lower end of the drift layer increases. If the electric field at the upper and lower end of the drift layer exceeds a certain level, electric field concentration does not stop and causes negative resistance, which results in destroying the device. This determines the avalanche withstand capability. In this embodiment, the vertical profile is sloped to decrease the electric field at the upper and lower end in advance. Thus negative resistance is unlikely to occur, and a high avalanche withstand capability can be obtained.

The embodiments of the invention have been described with reference to the examples. However, the invention is not limited thereto, but can be variously modified within the spirit of the invention.

For instance, any combinations of the above-described embodiments are included in a scope of the present invention. Further, in the above embodiments, it is assumed that the first conductivity type and the second conductivity type are n-type and p-type, respectively. However, the invention is practicable also when the first conductivity type and the second conductivity type are p-type and n-type, respectively.

The planar pattern of the MOS gate section and the super-junction structure is not limited to the striped configuration, but may be formed in a lattice or staggered configuration.

While the cross sections of the planar gate structure are shown, a trench gate structure may also be used.

The invention is practicable also when the p-type pillar layer 4 is in contact with the drain layer 2. Furthermore, the invention is practicable also when the super-junction structure is formed on the surface of the substrate on which an n⁻-type layer having a lower impurity concentration than the n-type pillar layer 3 is grown.

In the above description, silicon (Si) is used as the semiconductor in the MOSFETs. However, compound semiconductors such as silicon carbide (SiC) and gallium nitride (GaN), or wide bandgap semiconductors such as diamond can be also used as the semiconductor.

The invention has been described with reference to MOSFETs having a super-junction structure. However, the invention is also applicable to any devices having a super-junction structure, such as an SBD (Schottky barrier diode), a pin diode, and an IGBT (insulated gate bipolar transistor).

1. A semiconductor apparatus comprising:
a first first-conductivity-type semiconductor layer;
a second first-conductivity-type semiconductor layer provided on a major surface of the first first-conductivity-type semiconductor layer in a device region and a termination region outside the device region, the device region allowing a main current path to be formed therein in a vertical direction generally perpendicular to the major surface of the first first-conductivity-type semiconductor layer;
a third second-conductivity-type semiconductor layer being adjacent to the second first-conductivity-type semiconductor layer, provided on the major surface of the first first-conductivity-type semiconductor layer, and forming a periodic array structure in combination with the second first-conductivity-type semiconductor layer in a lateral direction generally parallel to the major surface of the first first-conductivity-type semiconductor layer;
a first main electrode electrically connected to the first first-conductivity-type semiconductor layer;
a fourth second-conductivity-type semiconductor region provided on the third second-conductivity-type semiconductor layer in the device region;
a fifth first-conductivity-type semiconductor region selectively provided in a surface of the fourth second-conductivity-type semiconductor region;
a second main electrode provided in contact with the fifth first-conductivity-type semiconductor region and the fourth second-conductivity-type semiconductor region;
a control electrode provided on the fifth first-conductivity-type semiconductor region, the fourth second-conductivity-type semiconductor region, and the second first-conductivity-type semiconductor layer via a gate insulating film;
a field insulating film provided on the second first-conductivity-type semiconductor layer and the third second-conductivity-type semiconductor layer in the termination region;
a first field plate electrode provided on the field insulating film and connected to the second main electrode or the control electrode; and
a second field plate electrode partly overlying the first field plate electrode through intermediary of an insulating film and extending on the field insulating film outside the first field plate electrode, the second field plate electrode being floating in potential.

2. The semiconductor apparatus according to claim 1, wherein
an impurity concentration in the second first-conductivity-type semiconductor layer of the termination region is lower than an impurity concentration in the second first-conductivity-type semiconductor layer of the device region, and
an impurity concentration in the third second-conductivity-type semiconductor layer of the termination region is lower than an impurity concentration in the third second-conductivity-type semiconductor layer of the device region.

3. The semiconductor apparatus according to claim 1, wherein a thickness of the insulating film below the first field plate electrode is varied stepwise.

4. The semiconductor apparatus according to claim 1, wherein the second field plate electrode is formed stepwise, and the insulating film below the floating field plate electrode has a larger thickness on outside than on inside of the second field plate electrode.

5. The semiconductor apparatus according to claim 1, wherein the field insulating film formed below the first field plate electrode and the field insulating film formed below the second plate electrode have a substantially equal thickness.

6. The semiconductor apparatus according to claim 1, further comprising:
a sixth first-conductivity-type semiconductor layer provided outside the periodic array structure in the termination region,
a second-conductivity-type field stop region formed in a surface portion of the sixth first-conductivity-type semiconductor layer in an outermost portion of the termination region, and
a field stop electrode connected to the field stop region and extending on the field insulating film.

7. The semiconductor apparatus according to claim 1, further comprising a third field plate electrode connected to the second field plate electrode and provided so as to overlie the second field plate electrode through an intermediary of the insulating film.

8. The semiconductor apparatus according to claim 1, wherein an impurity concentration in at least one of the second first-conductivity-type semiconductor layer and the third second-conductivity-type semiconductor layer varies in a direction substantially perpendicular to the major surface.

9. The semiconductor apparatus according to claim 8, wherein the impurity concentration in the third second-conductivity-type semiconductor layer is lower on a side of the first-conductivity-type semiconductor layer and higher on a side of the fourth second-conductivity-type semiconductor layer.

10. The semiconductor apparatus according to claim 9, wherein the impurity concentration in the second first-conductivity-type semiconductor layer is substantially constant in the direction substantially perpendicular to the major surface.

11. A semiconductor apparatus comprising:
a first first-conductivity-type semiconductor layer;
a second first-conductivity-type semiconductor layer provided on a major surface of the first first-conductivity-type semiconductor layer in a device region and a termination region outside the device region, the device region allowing a main current path to be formed therein in a vertical direction generally perpendicular to the major surface of the first first-conductivity-type semiconductor layer;
a third second-conductivity-type semiconductor layer being adjacent to the second first-conductivity-type semiconductor layer, provided on the major surface of the first first-conductivity-type semiconductor layer, and forming a periodic array structure in combination with the second first-conductivity-type semiconductor layer in a lateral direction generally parallel to the major surface of the first first-conductivity-type semiconductor layer;
a first main electrode electrically connected to the first first-conductivity-type semiconductor layer;
a fourth second-conductivity-type semiconductor region provided on the third second-conductivity-type semiconductor layer in the device region;
a fifth first-conductivity-type semiconductor region selectively provided in a surface of the fourth second-conductivity-type semiconductor region;
a second main electrode provided in contact with the fifth first-conductivity-type semiconductor region and the fourth second-conductivity-type semiconductor region;
a control electrode provided on the fifth first-conductivity-type semiconductor region, the fourth second-conductivity-type semiconductor region, and the second first-conductivity-type semiconductor layer via a gate insulating film;
a field insulating film provided on the second first-conductivity-type semiconductor layer and the third second-conductivity-type semiconductor layer in the termination region;
a first field plate electrode provided on the field insulating film and connected to the second main electrode or the control electrode;
a second field plate electrode partly overlying the first field plate electrode through intermediary of an insulating film and extending on the field insulating film outside the first field plate electrode, the second field plate electrode being floating in potential, and
a fourth field plate electrode extending on the field insulating film outside the first field plate electrode, the fourth field plate electrode being floating in potential, and the fourth field plate electrode being spaced from the second filed plate electrode.

12. The semiconductor apparatus according to claim 11, wherein
an impurity concentration in the second first-conductivity-type semiconductor layer of the termination region is lower than an impurity concentration in the second first-conductivity-type semiconductor layer of the device region, and
an impurity concentration in the third second-conductivity-type semiconductor layer of the termination region is lower than an impurity concentration in the third second-conductivity-type semiconductor layer of the device region.

13. The semiconductor apparatus according to claim 11, wherein a thickness of the insulating film below the first field plate electrode is varied stepwise.

14. The semiconductor apparatus according to claim 11, wherein the second field plate electrode is formed stepwise, and the insulating film below the floating field plate electrode has a larger thickness on outside than on inside of the second field plate electrode.

15. The semiconductor apparatus according to claim 11, wherein the field insulating film formed below the first field plate electrode and the field insulating film formed below the second plate electrode have a substantially equal thickness.

16. The semiconductor apparatus according to claim 11, further comprising:
a sixth first-conductivity-type semiconductor layer provided outside the periodic array structure in the termination region,
a second-conductivity-type field stop region formed in a surface portion of the sixth first-conductivity-type semiconductor layer in an outermost portion of the termination region, and
a field stop electrode connected to the field stop region and extending on the field insulating film.

17. The semiconductor apparatus according to claim 11, further comprising a third field plate electrode connected to the second field plate electrode and provided so as to overlie the second field plate electrode through an intermediary of the insulating film.

18. The semiconductor apparatus according to claim 11, wherein an impurity concentration in at least one of the second first-conductivity-type semiconductor layer and the third second-conductivity-type semiconductor layer varies in a direction substantially perpendicular to the major surface.

19. The semiconductor apparatus according to claim 18, wherein the impurity concentration in the third second-conductivity-type semiconductor layer is lower on a side of the first-conductivity-type semiconductor layer and higher on a side of the fourth second-conductivity-type semiconductor layer.

20. The semiconductor apparatus according to claim 19, wherein the impurity concentration in the second first-conductivity-type semiconductor layer is substantially constant in the direction substantially perpendicular to the major surface.
